(19) United States
(12) Patent Application Publication
(10) Pub. No.: US 2026/0227491 A1
(43) Pub. Date: Aug. 6, 2026

(54) DETACHABLE HANDHELD LASER SCANNER SYSTEM SUPPORTING MULTIPLE PLUG-IN COMBINATIONS

(71) Applicant: ZHUHAI 4DAGE TECHNOLOGY CO.,LTD, Zhuhai (CN)

(72) Inventors: Yan CUI, Zhuhai (CN); Shiting XU, Zhuhai (CN); Qiang LIU, Zhuhai (CN); Chunguang XU, Zhuhai (CN)

(21) Appl. No.: 19/636,845

(22) Filed: Apr. 1, 2026

(30) Foreign Application Priority Data
Sep. 19, 2025 (CN) 202511346909.7

(51) Int. Cl. G01S 7/481; G03B 17/56; H01F 7/13; H05K 5/02; H05K 5/06

(52) U.S. Cl. CPC G01S 7/4813; G03B 17/561; H05K 5/0221; H05K 5/061; H01F 7/13

(57) ABSTRACT

A detachable handheld laser scanner system supporting multiple plug-in combinations, including a main unit, an extension member and multiple external components. A housing of the main unit is provided with the extension member. The extension member includes an engagement cavity recessed on a side of the housing, a data interface provided on an inner wall of the engagement cavity and a clamping part movably provided in the housing. The engagement cavity has a first side wall and a second side wall oppositely provided in a second direction intersecting the first direction. The external components include a lidar module, a structured-light scanning module, an image acquisition module or a combination thereof. Each external component is provided with an engagement portion configured to engage with the engagement cavity. A surface of the engagement portion is provided with a data connector mating with the data interface.

### CROSS-REFERENCE TO RELATED APPLICATIONS

This application claims the benefit of priority from Chinese Patent Application No. 202511346909.7, filed on Sep. 19, 2025. The content of the aforementioned application, including any intervening amendments made thereto, is incorporated herein by reference in its entirety.

### TECHNICAL FIELD

This application relates to optical measurement equipment, and more particularly to a detachable handheld laser scanner system supporting multi plug-in combinations.

### BACKGROUND

Handheld laser scanners are widely used in fields such as industrial inspection, reverse engineering, and cultural relics preservation due to their portability and flexibility. Conventional handheld scanners typically integrate a single type of scanning module (e.g., a lidar module or a structured-light module), resulting in fixed functionality and limited adaptability to diverse application scenarios. For example, high-precision three-dimensional modeling requires point cloud data generated by laser lidar, while capturing fine details of small objects often relies on structured-light technology. In addition, texture fusion generally requires cooperation with an image acquisition module. Existing devices usually realize these different functions through separate device models, which requires users to purchase multiple sets of equipment, leading to higher costs and cumbersome operation.

Although detachable scanning devices have been proposed in the prior art, they generally suffer from the following deficiencies:
1. Limited functional expandability: External components typically support connection of only a single module, making it difficult to achieve multimodal data fusion (e.g., collaborative processing of point cloud data, structured-light data, and image textures) through combinations of multiple plug-ins.
2. Insufficient connection reliability: The mechanical connection structures are relatively simple, and shaking during operation may lead to poor contact of data interfaces. Moreover, auxiliary fixing mechanisms such as electromagnetic attraction are generally absent, thereby affecting scanning stability.
3. Lack of intelligent adaptation: The host device is unable to automatically identify the type of an external component, requiring manual configuration of drivers and parameters, which increases operational complexity and makes the system prone to errors.

Accordingly, there is an urgent need for a system capable of solving at least one of the above problems.

### SUMMARY

An object of the disclosure is to provide a detachable handheld laser scanner system supporting multiple plug-in combinations, which aims to solve the problem that high-precision three-dimensional modeling requires point cloud data from a laser lidar module, whereas capturing fine details of micro targets relies on structured light technology, and image-texture fusion requires an image acquisition module. In conventional devices, these functions are typically realized by separate standalone systems, which forces the user to purchase multiple sets of equipment, resulting in high cost and complicated operation.

Technical solutions of the present disclosure are described as follows.

A detachable handheld laser scanner system supporting multiple plug-in combinations, comprising:
a main unit;
an extension member; and
a plurality of external components;
wherein a housing of the main unit is provided with the extension member;
the extension member comprises an engagement cavity, a data interface and a clamping part; the engagement cavity is recessed on a side of the housing along a first direction; the data interface is provided on an inner wall of the engagement cavity; and a clamping part is movably provided in the housing;
the engagement cavity has a first side wall and a second side wall opposite to each other in a second direction, wherein the second direction intersects intersecting the first direction;
the clamping part is provided with a limiting portion configured to act on the plurality of external components;
the plurality of external components comprise a lidar module, a structured-light scanning module, an image acquisition module or a combination thereof;
each of the plurality of external components is provided with an engagement portion configured to engage with the engagement cavity;
a surface of the engagement portion is provided with a data connector configured to mate with the data interface;
in response to a case that each of the plurality of external components is inserted into the engagement cavity along the first direction, the engagement portion is engaged with the engagement cavity in the first direction, the clamping part is configured to be operated to cause the limiting portion to abut against the engagement portion together with the first side wall in the second direction to achieve a locked state between the main unit and the plurality of external components, and the data connector is configured to mate with the data interface to establish data communication;
in response to a case that the clamping part is operated to allow a distance between the limiting portion and the first side wall in the second direction to be not smaller than a distance between the first side wall and the second side wall, each of the plurality of external components is configured to disengage from the engagement cavity along the first direction to achieve an unlocked state; and
the main unit is configured to be selectively connected to corresponding one or more of the plurality of external components according to different application scenarios through a detachable connection between the extension member and the corresponding one or more of the plurality of external components, so as to realize a point-cloud accuracy enhancement function, a micro-target modeling function, an image-texture fusion function or a combination thereof.

Compared to the prior art, the present disclosure has the following beneficial effects.

The present disclosure provides the detachable handheld laser scanner system supporting multiple plug-in combinations. Through the detachable connection between the extension member and the corresponding one or more of external components, the main unit can be selectively connected to the lidar module, the structured-light scanning module, the image acquisition module or a combination thereof according to the requirements of a given application scenario, thereby enabling flexible switching and combination of functions such as point-cloud accuracy enhancement, micro-target modeling, and image-texture fusion, significantly improving device versatility and reducing user cost. The guide structures of both the engagement portion and the engagement cavity, together with an electromagnetic adsorption layer and a magnetic base, ensure precise alignment and secure connection of the external components upon insertion. The design of the contact-type data connector and the elastic contact piece set ensures stable and efficient data transmission. The main control chip of the main unit includes an identification module configured to automatically read the identification information of the external components and retrieve a corresponding driver program and scanning parameters, without manual configuration, thereby improving operational convenience. A multimodal data registration algorithm is configured to deeply fuse data from different modules, thereby significantly enhancing scanning accuracy and modeling performance.

It should be understood that the foregoing general description and the following detailed description are merely exemplary and explanatory, and are not intended to limit the present disclosure.

### BRIEF DESCRIPTION OF THE DRAWINGS

In order to illustrate the technical solutions in the present disclosure more clearly, the accompanying drawings needed in the description of the embodiments will be briefly described below. It is evident that presented in the following accompanying drawings are only some embodiments of the present disclosure, instead of all embodiments. For those of ordinary skill in the art, other accompanying drawings can be obtained based on these accompanying drawings without making creative effort.

FIG. 1 is a structural view of a main unit and a handle in a combined state of a handheld radar device of the present disclosure;

FIG. 2 is a structural view of a second protrusion of the handheld radar device of the present disclosure;

FIG. 3 is an exploded view of a protective cover and the main unit according to Example 1 of the handheld radar device of the present disclosure;

FIG. 4 is a structural view of the protective cover and the main unit in a combined state according to Example 1 of the handheld radar device of the present disclosure;

FIG. 5 structurally illustrates an engagement between the protective cover and the main unit according to Example 1 of the handheld radar device of the present disclosure;

FIG. 6 is a structural view of the main unit and a main extension component in a combined state according to a first embodiment of Example 2 of the handheld radar device of the present disclosure;

FIG. 7 is a partial structural view of the main extension component according to the first embodiment of Example 2 of the handheld radar device of the present disclosure;

FIG. 8 is a cross-sectional view of the main extension component according to the first embodiment of Example 2 of the handheld radar device of the present disclosure;

FIG. 9 is a structural view of an abutting member according to the first embodiment of Example 2 of the handheld radar device of the present disclosure;

FIG. 10 is a structural view of the main extension component according to a second embodiment of Example 2 of the handheld radar device of the present disclosure;

FIG. 11 is a structural view of the main unit and the main extension component in a combined state according to the second embodiment of Example 2 of the handheld radar device of the present disclosure;

FIG. 12 is an exploded view of the main extension component according to a third embodiment of Example 2 of the handheld radar device of the present disclosure;

FIG. 13 is a structural view of the main unit and the main extension component in a combined state according to the third embodiment of Example 2 of the handheld radar device of the present disclosure;

FIG. 14 is an exploded view of the main unit and an auxiliary extension component according to Example 3 of the handheld radar device of the present disclosure;

FIG. 15 is a structural view of the main unit, the auxiliary extension component and the handle in a combined state according to Example 3 of the handheld radar device of the present disclosure; and

FIG. 16 is a structural view of the auxiliary extension component according to Example 3 of the handheld radar device of the present disclosure.

It should be understood that the foregoing general description and the following detailed description are merely exemplary and explanatory, and are not intended to limit the present disclosure.

### DETAILED DESCRIPTION OF EMBODIMENTS

The technical solutions in the embodiments of the present disclosure will be described clearly and completely below in conjunction with the accompanying drawings. It is obvious that the described embodiments are merely some embodiments of the present disclosure, instead of all embodiments. Based on the embodiments in the present disclosure, all other embodiments obtained by those of ordinary skill in the art without making creative effort shall fall within the scope of the present disclosure defined by the appended claims.

The flowcharts shown in the accompanying drawings are for illustrative purposes only and do not necessarily include all of the content and operations/steps, nor are the operations/steps required to be performed in the order shown. For example, certain operations/steps may be decomposed, combined, or partially merged, and the actual execution order may vary depending on the specific circumstances.

It should be understood that, for the sake of clarity in describing the technical solutions of the embodiments of the present disclosure, the terms “first” and “second” are used herein to distinguish identical or similar elements or items having substantially the same function or effect. Those skilled in the art will recognize that such terms do not impose any limitation on quantity or order of execution, nor do they necessarily indicate that the elements or items are distinct.

It should be understood that the terminology used herein is for the purpose of describing particular embodiments only and is not intended to limit the present disclosure. As used herein and in the appended claims, the singular forms “a”, “an” and “the” are intended to include the plural forms as well, unless the context clearly indicates otherwise.

It should be further understood that the term “and/or” as used in this specification and the appended claims refers to any and all possible combinations of one or more of the associated listed items, and includes such combinations.

The embodiments will be described in detail below with reference to the accompanying drawings. Unless otherwise indicated, the embodiments and features described herein may be combined with one another.

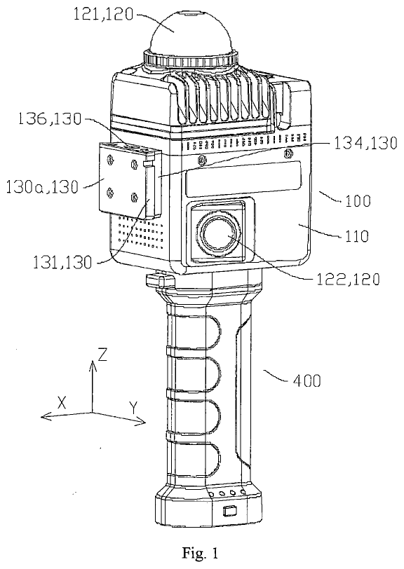

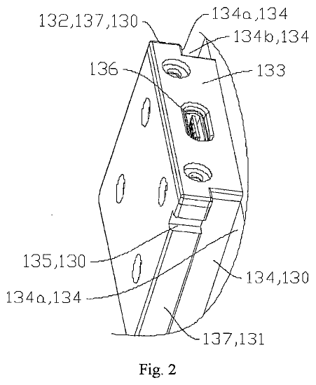

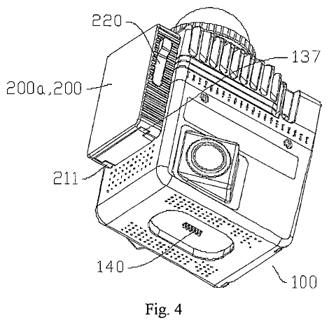

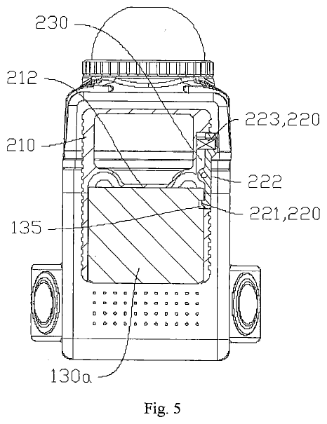

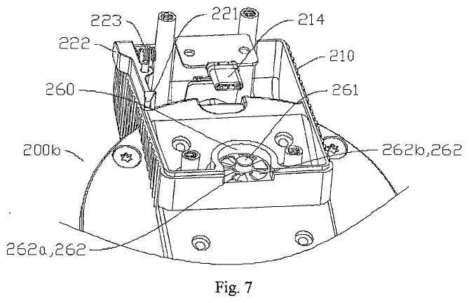

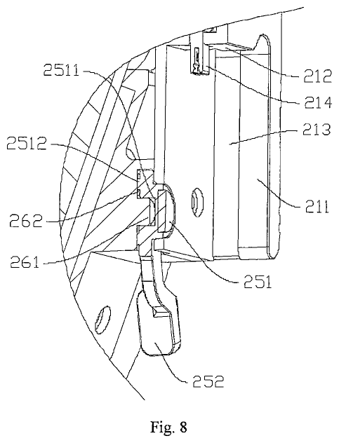

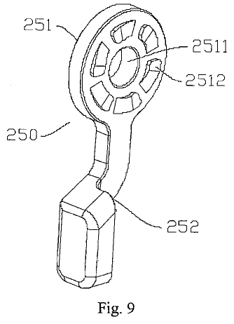

As shown in FIGS. 1-14, an embodiment of the present disclosure provides a detachable handheld laser scanner system supporting multiple plug-in combinations, including a main unit, an extension member and a plurality of external components. A housing of the main unit is provided with the extension member. The extension member includes an engagement cavity, a data interface and a clamping part. The engagement cavity is recessed on a side of the housing along a first direction. The data interface is provided on an inner wall of the engagement cavity. The clamping part is movably provided in the housing. The engagement cavity has a first side wall and a second side wall opposite to each other in a second direction, where the second direction intersects the first direction. The clamping part is provided with a limiting portion configured to act on the plurality of external components. The plurality of external components include a high-precision lidar module, a structured-light scanning module, an high-resolution image acquisition module or a combination thereof. Each of the plurality of external components is provided with an engagement portion configured to engage with the engagement cavity. A surface of the engagement portion is provided with a data connector configured to mate with the data interface. When each of the plurality of external components is inserted into the engagement cavity along the first direction, the engagement portion is engaged with the engagement cavity in the first direction, the clamping part is configured to be operated to cause the limiting portion to abut against the engagement portion together with the first side wall in the second direction to achieve a locked state between the main unit and the plurality of external components, and the data connector is configured to mate with the data interface to establish data communication. When the clamping part is operated to allow a distance between the limiting portion and the first side wall in the second direction to be not smaller than a distance between the first side wall and the second side wall, each of the plurality of external components is configured to disengage from the engagement cavity along the first direction to achieve an unlocked state. The main unit is configured to be selectively connected to corresponding one or more of the plurality of external components according to different application scenarios through a detachable connection between the extension member and the corresponding one or more of the plurality of external components, so as to realize a point-cloud accuracy enhancement function, a micro-target modeling function, an image-texture fusion function or a combination thereof.

Specifically, the present disclosure provides a modular and detachable handheld laser scanner system, in which detachable connections between the main unit and external components enable flexible expansion of multi-modal scanning functions. The system primarily includes the main unit, the extension member and external components. Through a coordinated design of mechanical structures such as a clamping part, guiding structures, and electromagnetic attraction, together with electrical connections including data interfaces and driver adaptation, the system enables rapid installation, stable locking, and intelligent function invocation of the external components, thereby satisfying high-precision three-dimensional scanning requirements in various application scenarios.

The housing of the main unit is designed to be handheld and portable, with a status indicator light and a touch display screen for human-machine interaction integrated on a surface thereof, and core components such as a main control chip, a power supply module and a storage module provided in the housing.

The extension member includes the engagement cavity recessed on the side of the housing along the first direction (defined as the “front-to-back direction” or “insertion direction”), where a contour of an inner wall of the engagement cavity is configured to match an outer contour of an engagement portion of each external component, forming a closely fitting engagement. The engagement cavity has the first side wall and the second side wall along the second direction, where the second direction intersects the first direction (the second direction defined as the “left-to-right direction” or “lateral direction”), and the first side wall and the second side wall are configured to restrict lateral movement of the external components. The data interface is provided on the inner wall of the engagement cavity, and includes an elastic contact piece set (a contact-type interface) electrically connected to the main control chip of the main unit via a flexible printed circuit board for data transmission and power supply. The clamping part is movably provided within the housing, and includes a push rod configured to slide laterally. A first end of the push rod is configured to extend outside the housing to form an operating portion (such as a raised handle or button), and a second end of the push rod is oriented toward the engagement cavity, and is provided with a first wedge-shaped protrusion (a limiting portion). The wedge-shaped protrusion is inclined toward the first side wall, and is configured to engage with a limiting slot of the external component to achieve a locked state.

The external components include the high-precision lidar module for long-range, high-accuracy point-cloud acquisition, the structured-light scanning module for micro-target detail modeling, and the high-resolution image acquisition module for capturing texture images, which can be used individually or in combination.

The engagement portion is shaped to match the engagement cavity. Two side walls of the engagement portion are each provided with a guide rib extending along the first direction. The guide rib is configured to slidably engage with a corresponding guide groove on the inner wall of the engagement cavity to ensure precise alignment upon insertion. A data connector (contact-type) is provided on a surface of the engagement portion to mate with the data interface. The limiting slot is formed on a side of the engagement portion to engage with a second wedge-shaped protrusion of the clamping part. A rear end of the engagement portion is provided with an electromagnetic adsorption layer (e.g., ferromagnetic material). The electromagnetic adsorption layer is configured to cooperate with a magnetic base (electromagnetic coil) at a bottom of the engagement cavity to generate an electromagnetic attraction force.

The installation and locking process of the external components includes the following steps.
Step (1) Insertion and mating: Each external component is inserted into the engagement cavity along the first direction (e.g., front-to-back direction), such that guide ribs of the engagement portion slide along corresponding guide grooves of the engagement cavity to ensure lateral alignment. Simultaneously, the electromagnetic adsorption layer of the engagement portion approaches the magnetic base at the bottom of the engagement cavity, and the data connector contacts the elastic contact piece set of the data interface, thereby establishing an initial physical connection.
Step (2) Mechanical locking: The push rod is pushed by a user toward the first side wall via the operating portion (e.g., laterally to the left). The push rod drives the wedge-shaped protrusion to move laterally, and an inclined surface of the wedge-shaped protrusion engages the limiting slot the external component until the wedge-shaped protrusion and the first side wall collectively abut against two sides of the engagement portion (in the second direction), thereby forming a mechanical locked state. At this point, the magnetic base is powered by the power supply module, and the electromagnetic adsorption layer interacts with the magnetic base to generate the electromagnetic attractive force, assisting in securing the external components and preventing wobbling.
Step (3) Data communication and function activation: The main control chip sends an identity query instruction to the external components through the data interface and receives identification information (e.g., an ID code of the high-precision lidar module). The main control chip retrieves a corresponding driver program from a preset component driver library to initialize corresponding hardware (e.g., a lidar emission unit). Simultaneously, the touch display screen presents selectable scenarios (e.g., “point-cloud scanning” or “micro-target modeling”). Upon user selection, the main control chip calls the matching a scanning parameter configuration file (e.g., laser emission frequency, structured-light projection period) to activate the corresponding function.

The unlocking and removal process of the external components includes the following steps.
Step (1) Releasing the mechanical lock: The user pulls the operating portion in a direction away from the first side wall (e.g., pulling to the right). The push rod overcomes a restoring force of a return spring (one end of the return spring is connected to the push rod, and the other end of the return spring is fixed to an inner wall of the housing, such that the return spring naturally biases the wedge-shaped protrusion away from the first side wall in a normal state), thereby driving the wedge-shaped protrusion to move laterally until a distance between the wedge-shaped protrusion and the first side wall is not less than a distance between the first side wall and the second side wall (i.e., greater than a lateral width of the engagement portion), thereby releasing the engagement portion from positional restriction.
Step (2) Deactivation of electromagnetic attraction and removal: After detecting the unlocking operation, the main control chip controls the power supply module to cut off power supplied to the magnetic base, such that the electromagnetic attractive force disappears. The user then pulls the external components out along the first direction, whereby the data connector is separated from the data interface, thereby completing removal.

Point-cloud accuracy enhancement (lidar module): After raw point cloud data is acquired by the lidar module, the main control chip invokes a point-cloud denoising algorithm to remove noise points through outlier filtering (e.g., a Random Sample Consensus (RANSAC) algorithm), and then optimizes point-cloud distribution through density equalization processing (e.g., voxel grid downsampling), thereby improving the accuracy of subsequent modeling.

Micro-target modeling (structured-light module): A structured-light module projects Gray-code fringe patterns onto a target surface, and an image sensor captures deformed fringe images. The main control chip parses fringe phase information based on a Gray code decoding algorithm and calculates three-dimensional coordinates of points on the target surface according to a triangulation principle, thereby generating high-density three-dimensional point cloud data suitable for modeling micro-scale structures such as precision components and cultural relic reliefs.

Image-texture fusion (multi-module combination): When both the high-precision lidar module and the image acquisition module are simultaneously selected, the main control chip executes a multimodal data registration algorithm. Feature points in the images (e.g., Scale-Invariant Feature Transform (SIFT) features) are first extracted and matched with three-dimensional coordinates in the point cloud data, generating a texture-point cloud mapping table. RGB texture information is then mapped onto the corresponding coordinates of the point cloud model, enabling reconstruction of a realistic three-dimensional model with texture. Mechanical engagement (wedge-shaped protrusion and limiting slot) combined with electromagnetic attraction (magnetic base and electromagnetic adsorption layer) ensures that the external components remain securely fixed during scanning, thereby addressing poor contact issues commonly observed in conventional plug-in connections.

The identification module automatically matches driver programs and scanning parameters without manual configuration. The algorithm library dynamically invokes processing logic (e.g., point-cloud denoising, Gray-code decoding) according to the module type, thereby enabling a plug-and-play hardware and automatically adaptive software integrated experience.

By freely combining external components (e.g., lidar module, structured-light scanning module and image acquisition module simultaneously selected), the system supports multimodal data acquisition and fusion, overcoming the limitations of conventional scanners with single functions, and meeting the requirements of various application scenarios such as industrial inspection, cultural relic preservation and reverse engineering.

Example application scenarios of the system include: Industrial quality inspection: the high-precision lidar module is inserted to perform high-precision point-cloud scanning of automotive body panel molds, and surface defects are detected in combination with denoising algorithms; Cultural relics digitization: structured-light and image acquisition modules are combined to capture three-dimensional details and color textures of decorative patterns of bronze artifacts, generating high-precision digital models suitable for permanent preservation; Reverse engineering: lidar and structured-light modules are used simultaneously to rapidly construct three-dimensional models of complex curved objects, with texture fusion enhancing model realism and shortening modeling cycles. Through the foregoing technical solutions, the present disclosure achieves a “modular hardware expansion with intelligent software adaptation” for handheld scanners, significantly outperforming conventional devices in terms of structural design, connection reliability, and functional flexibility, thereby providing an efficient solution for scenario-based applications of three-dimensional scanning technology.

In some embodiments, an outer contour of the engagement portion is configured to match a contour of the inner wall of the engagement cavity. At least two side walls of the engagement portion are each provided with a guide rib extending along the first direction. The inner wall of the engagement cavity is provided with a guide groove configured to slidably receive the guide rib. The data connector is configured as a contact-type connector. The data interface is configured as an elastic contact piece set adapted to the contact-type connector. The elastic contact piece set is electrically connected to the main control chip of the main unit via the flexible printed circuit board.

The engagement portion of the external component is precisely aligned with the engagement cavity of the main unit's extension member through a guiding structure, while the data interface employs a contact-type elastic connection scheme. Specifically, two side walls of the engagement portion are each provided with the guide rib extending along the first direction, and the guide groove are provided on the inner wall of the engagement cavity to establish a sliding fit. The data connector is the contact-type connector, and the data interface is the elastic contact piece set electrically connected to the main control chip via the flexible printed circuit board.

Upon insertion of the external component, the guide ribs of the engagement portion slide along the guide grooves of the engagement cavity, ensuring uniqueness of the insertion direction (first direction) and precise lateral alignment (second direction), thereby preventing misalignment between the data connector and the data interface due to tilting.

The contact-type connector has a gold-plated surface (or coated with another conductive material) and is embedded in a surface of the engagement portion. The elastic contact piece set is made of an elastic metal such as phosphor bronze, fixed to the inner wall of the engagement cavity, and maintains close contact with the contact-type connector through elastic deformation when engaged. The flexible printed circuit board transmits electrical signals to the main control chip of the main unit.

The engagement between the guide ribs and the guide grooves ensures that the external component does not shift during insertion, thereby preventing connection failure due to manual alignment errors. The elastic pressing design of the elastic contact piece set compensates for contact loosening caused by vibrations of the handheld device, while the flexible printed circuit board accommodates slight displacements during insertion and removal of the component, ensuring reliable data communication.

In some embodiments, the clamping part includes a push rod slidably provided in the housing. The first end of the push rod is configured to extend outside the housing to form the operating portion, and the second end of the push rod is oriented toward the engagement cavity and is provided with the limiting portion. The limiting portion is configured as a wedge-shaped protrusion inclined toward the first side wall. The engagement portion is provided with a limiting slot at a position corresponding to the wedge-shaped protrusion, and the limiting slot is configured to engage with the wedge-shaped protrusion. When the operating portion is pushed along the second direction, the wedge-shaped protrusion is configured to be inserted into the limiting slot and to abut against the first side wall to achieve the locked state.

The clamping part adopts a mechanical locking structure of the wedge-shaped protrusion and the limiting slot, and the external component is locked by driving the push rod through the operation portion. Specifically, the first end of the push rod is configured to extend outside the housing to form the operation portion (e.g., a push-pull button), while the second end of the push rod is provided with the wedge-shaped protrusion (limiting portion) inclined toward the first side wall of the engagement cavity. The limiting slot is provided at a corresponding position of the engagement portion, which cooperates with the wedge-shaped protrusion to achieve a mechanical lock.

The locking process is performed by the user pushing the operation portion toward the first side wall along the second direction (e.g., laterally), causing the push rod to drive the wedge-shaped protrusion to move laterally. The inclined surface of the wedge-shaped protrusion engages with the limiting slot until the bottom surface of the wedge-shaped protrusion and the first side wall collectively abut against the two side walls of the engagement portion, thereby achieving a lateral constraint that prevents the external component from disengaging along the first direction.

An inclined angle of the wedge-shaped protrusion (e.g., 30°) is determined through mechanical calculation to ensure that the contact surface between the wedge-shaped protrusion and the limiting slot can withstand external forces during the scanning process (e.g., hand-held vibrations). At the same time, the inclined surface is designed to facilitate self-alignment upon insertion, allowing the wedge-shaped protrusion to slide into the limiting slot without requiring perfect initial alignment.

In some embodiments, a return spring is provided between the push rod and the housing. A first end of the return spring is connected to the push rod, and a second end of the return spring is connected to the inner wall of the housing. When no external force is applied to the operation portion, the return spring is in a naturally-extended state, and a distance between the wedge-shaped protrusion and the first side wall is greater than a width of the limiting slot. When an external force is applied to the operation portion in a direction away from the first side wall, the distance between the wedge-shaped protrusion and the first side wall increases to be not less than the distance between the first side wall and the second side wall, thereby achieving the unlocked state.

Automatic restoration of the unlocked state is achieved by adding the return spring to the clamping part. Specifically, the return spring is connected between the push rod and the inner wall of the housing. In a natural state, the return spring pushes the push rod so that the wedge-shaped protrusion is biased away from the first side wall. During unlocking, an external force pulls the operation portion to compress the return spring, thereby increasing the distance between the wedge-shaped protrusion and the first side wall and releasing the positional restriction.

The spring is installed such that the second end of the return spring is fixed to a protruding boss on the inner wall of the housing, and the first end of the return spring is connected to a rear end of the push rod. An axis of the return spring is parallel to the second direction. When the return spring is in a naturally-extended state, the distance between the wedge-shaped protrusion and the first side wall is greater than the width of the limiting slot, such that an initial state is the unlocked state.

The unlocking operation is performed by a user pulling the operation portion a direction away from the first side wall (e.g., pulling rightward). The push rod moves in the second direction against a spring force until the distance between the wedge-shaped protrusion and the first side wall is greater than or equal to a lateral width of the engagement portion (i.e., the distance between the first side wall and the second side wall), at which point the external component can be freely withdrawn.

In some embodiments, a sealing ring is provided at an opening edge of the engagement cavity. The sealing ring is configured to extend along the first direction and abut against a front-end surface of the engagement portion to enable the detachable connection between the extension member and the corresponding one or more of the plurality of external components. A bottom of the engagement cavity is provided with a pressure sensor. The pressure sensor is electrically connected to the main control chip of the main unit, and is configured to detect whether the corresponding one or more of external components is fully inserted into the engagement cavity.

By additionally providing the sealing ring and the pressure sensor in the engagement cavity, sealing performance and insertion detection capability are improved. Specifically, the sealing ring is provided at the opening edge of the engagement cavity. The sealing ring is configured to extend along the first direction and abut against the front-end surface of the engagement portion. The bottom of the engagement cavity is provided with the pressure sensor. The pressure sensor is electrically connected to the main control chip to detect whether the corresponding one or more of the external components is fully inserted.

In the sealing design, the sealing ring is made of silicone rubber and has a lip-shaped or O-shaped cross section, and is embedded in an annular groove at the opening of the engagement cavity. When the external component is inserted, the front-end surface of the engagement portion abuts against the sealing ring to form a dustproof and waterproof sealing structure, with a protection rating reaching IP54 or above.

In the insertion detection design, the pressure sensor is a film-type pressure sensor fixed at the bottom of the engagement cavity. When the external component is fully inserted, a rear end of the engagement portion abuts against the pressure sensor, and a signal generated by the pressure sensor triggers the main control chip to determine that the connection is completed; otherwise, the connection is determined to be incomplete and an alarm is issued through the status indicator light.

When a selected one of the plurality of external components is the high-precision lidar module, the main control chip of the main unit is configured to invoke a point-cloud denoising algorithm to perform outlier filtering and density equalization on point cloud data acquired by the high-precision lidar module, thereby realizing the point-cloud accuracy enhancement function. When a selected one of the plurality of external components is the structured-light scanning module, the main control chip of the main unit is configured to parses fringe images projected by the structured-light scanning module based on a Gray code decoding algorithm to generate three-dimensional point cloud data of a micro target, thereby realizing the micro-target modeling function.

For different external components, the main control chip executes dedicated algorithms to enhance functionality. Specifically, when the high-precision lidar module is selected, the point-cloud denoising algorithm is invoked, including outlier filtering and density equalization; when the structured-light scanning module is selected, the three-dimensional point cloud data of the micro target is generated based on the Gray code decoding algorithm.

Point-cloud denoising includes the following processes: outlier filtering and density equalization. For outlier filtering, the RANSAC algorithm is used to fit planes or surfaces in the point cloud data, identifying and removing points that deviate from the main surface (e.g., noise caused by environmental reflections during scanning). Density equalization is performed via voxel-grid downsampling, performing downsampling in high-density regions and interpolation in low-density regions, thereby achieving uniform overall point-cloud density and improving subsequent modeling efficiency. Gray-code decoding is performed by projecting multiple Gray-code fringe images (e.g., 8-bit Gray code, 8 images in total) using the structured-light module, and an image sensor captures the resulting deformed fringes. The main control chip decodes the phase value of each pixel from the grayscale variation sequence of the fringes, and computes the three-dimensional coordinates based on calibration parameters of a stereo camera, thereby generating a micro-target point cloud with millimeter-level accuracy.

In some embodiments, when among the plurality of external components, the high-resolution image acquisition module and the high-precision lidar module are simultaneously selected, the main control chip of the main unit is configured to execute a multimodal data registration algorithm, including the following steps. A surface texture image of a target is acquired through the high-resolution image acquisition module, and point cloud data of the target is acquired through the high-precision lidar module. Feature matching is performed based on feature points in the texture image and three-dimensional coordinates in the point cloud data to generate a texture-point cloud mapping table. The texture image is fused into the point cloud data according to the texture-point cloud mapping table, thereby achieving the image-texture fusion function.

By supporting multimodal data fusion when the external components are selected in combination, precise registration between image texture and point cloud data is achieved. Specifically, the high-resolution image acquisition module and the lidar module are simultaneously selected. A feature-matching algorithm is executed by the main control chip to generate the texture-point cloud mapping table, thereby enabling texture fusion.

Data acquisition is performed by acquiring an RGB texture image of a target using the high-resolution image acquisition module (with a resolution≥1920×1080), and acquiring point cloud data with coordinates using the high-precision lidar module (with an accuracy of ±0.1 mm).

Feature Matching: Feature points (e.g., edges, corners) are extracted from the image using a Scale-Invariant Feature Transform (SIFT) or Speeded-Up Robust Features (SURF) algorithm. Simultaneously, normal vectors are computed from the point cloud data to extract three-dimensional feature points. Using a Euclidean distance matching method, two-dimensional feature point coordinates are associated with three-dimensional point cloud coordinates, generating at least ten matching pairs to establish a texture-point cloud mapping relationship. Texture Fusion: Based on the mapping relationship table, each point cloud coordinate is assigned the corresponding pixel RGB value to generate a textured three-dimensional model in Polygon File Format (PLY) or Wavefront Object (OBJ) format, which can be visualized in professional software.

In some embodiments, a surface of the housing of the main unit is provided with a status indicator light and a touch display screen. The status indicator light is electrically connected to the main control chip, and is configured to indicate connection states of the plurality of external components. The touch display screen is configured to receive a scenario selection instruction input by a user. The main control chip is configured to retrieve, in response to the scenario selection instruction, a scanning parameter configuration file corresponding to selected one or more of the plurality of external components. The scanning parameter configuration file includes a laser emission frequency, a structured-light projection period and an image acquisition frame rate.

A human-machine interface is integrated in the main unit, including the status indicator light and the touch display screen, to support scenario-based parameter configuration. Specifically, the connection status of the external components is indicated by the status indicator light (e.g., a solid green light indicates a locked state, and a flashing red light indicates incomplete insertion). A scenario selection instruction is received by the touch display screen from a user, and corresponding scanning parameters, such as the laser emission frequency, the structured-light projection period, and the image frame rate, are invoked by the main control chip.

The status is indicated by RGB tri-color LEDs embedded in a top of the housing of the main unit. A blue breathing light indicates a standby state; a solid green light indicates a normal connection; a fast-flashing red light indicates that an incomplete insertion is detected by the pressure sensor; and a flashing yellow light indicates a data transmission abnormality.

Parameter configuration is performed via the touch display screen, which presents a list of selectable scenarios (e.g., “industrial scanning”, “cultural relics modeling” and “reverse engineering”). Upon selection of a scenario, the corresponding parameters are retrieved by the main control chip from a preset configuration file according to a type of the external component, (e.g., in an industrial scenario, a laser emission frequency is set to 100 kHz, and a structured light projection period is set to 50 ms), and the module hardware is automatically configured accordingly.

In some embodiments, the main control chip of the main unit includes an identification module. The identification module is configured to:
send, through the data interface, an identity query instruction to the corresponding one or more of the plurality of external components when the corresponding one or more of the plurality of external components is inserted into the engagement cavity and the data connector is mated with the data interface;
receive identification information returned from the corresponding one or more of the plurality of external components; and
retrieve a corresponding driver program from a preset component driver library based on the identification information to control operation of corresponding hardware and perform data format conversion.

The identification module is embedded in the main control chip to enable automatic recognition and driver adaptation of external components. Specifically, after the data interface is mated, the identity query instruction is sent, and the identification information returned by the external component (e.g., “LIDAR-01” for the high-precision lidar module) is received, whereby the corresponding driver program is retrieved.

The external component is embedded with an Electrically Erasable Programmable Read-Only Memory (EEPROM) storage chip, which stores a unique type identifier and a driver version number. The data connector includes Inter-Integrated Circuit/Serial Peripheral Interface (I²C/SPI) communication pins. A read instruction (e.g., “0x01”) is sent from the main control chip via the data interface, and a 16-bit binary identifier is returned by the component, with the first 8 bits representing the module type and the last 8 bits representing the version number. A component driver library is preset in a storage area of the main unit, each driver program containing a hardware control instruction set (e.g., pulse emission control of the lidar module) and a data format conversion algorithm (e.g., conversion of raw point cloud data into a standard Polygon File Format (PLY)). A corresponding driver is matched and loaded according to the received identifier.

In some embodiments, a rear end of the engagement portion of each external component is provided with an electromagnetic adsorption layer. A bottom of the engagement cavity is provided with a magnetic base corresponding to the electromagnetic adsorption layer, and the magnetic base is configured to cooperate with the electromagnetic adsorption layer. The magnetic base is electrically connected to a power supply module of the main unit. When the corresponding one or more of the external components is inserted into the engagement cavity and in the locked state, the power supply module of the main unit is configured to supply power to the magnetic base, such that an electromagnetic attraction force is generated between the electromagnetic adsorption layer and the magnetic base. When the corresponding one or more of the external components are in the unlocked state, the power supply module of the main unit is configured to cut off power supply to the magnetic base, such that the electromagnetic attraction force disappears.

Electromagnetic attraction is employed to assist in securing the external components, thereby enhancing the connection stability. Specifically, the rear end of the engagement portion is provided with the electromagnetic adsorption layer (ferromagnetic material, e.g., soft iron), and the bottom of the engagement cavity is provided with the magnetic base (electromagnetic coil). Upon locking, the magnetic base is energized to generate the electromagnetic attractive force; upon unlocking, the power is cut off to demagnetize the magnetic base.

The magnetic base consists of a coil wound with enameled wire and an iron core, fixed at the bottom of the engagement cavity, and is powered by the power supply module (voltage: 5 V, current: 0.5 A) to generate an attractive force of ≥5 N. The electromagnetic adsorption layer is a rectangular iron-nickel alloy sheet embedded at the rear end of the engagement portion, aligned with the magnetic base, with an insertion gap of ≤1 mm to ensure effective magnetic coupling. When the operating portion is pushed to a locked position, a signal from the pressure sensor triggers the power supply module to energize the magnetic base, so that the adsorption layer and the magnetic base are magnetically secured. Upon unlocking, the operating portion is pulled to a release position, and the main control chip simultaneously cuts off power to the magnetic base, causing the magnetic force to disappear and facilitating detachment.

In some embodiments, on the basis of conventional point cloud denoising, a lightweight convolutional neural network (a PointNet++-derived model) is introduced to enable intelligent identification of noise points and semantic completion of missing regions in complex scenarios. A target semantic classification module is embedded in the algorithm, so that a completion strategy is dynamically adjusted according to a type of a scanned object (e.g., a mechanical part, a biological organ), thereby supporting high-precision three-dimensional reconstruction of incomplete objects.

Model Training and Deployment: Training Phase: A point cloud denoising and completion model is pretrained using the ShapeNet dataset, where an input is an incomplete point cloud containing Gaussian noise/outliers, and an output is a denoised and completed point cloud. For specific scenarios, such as industrial parts and cultural relic reliefs, the model parameters are fine-tuned via transfer learning. Lightweight processing: Model pruning and quantization techniques are employed to compress the model size to within 5 MB, adapting to the computational power limitations of the main control chip of the main unit (e.g., an Nvidia Jetson Nano embedded platform).

Real-Time Processing Flow: Data Input: Raw point clouds acquired by the external component (e.g., a lidar module) are preprocessed (e.g., invalid points are removed) and then input into an algorithm engine of the main control chip. Semantic Classification: The model first determines an object category through a feature extraction layer (multilayer perceptron combined with farthest point sampling) and outputs a probability matrix. For example, if a “gear” is identified, a mechanical part completion mode is activated; if a “terracotta figurine” is identified, a surface smoothing completion strategy is enabled. Denoising and Completion: Based on a classification result, outlier noise points are removed through a denoising branch (density-aware convolution), and point cloud coordinates of missing regions are predicted through a completion branch (generative adversarial network (GAN) structure) to generate complete point cloud data.

In some embodiments, a scanning efficiency optimization model is constructed, and an optimal scanning path for a target object is automatically generated by using a reinforcement learning (RL) algorithm. The algorithm combines real-time point cloud density feedback with a motion trajectory of the handheld device, such that a scanning speed and an angle are dynamically adjusted to reduce overlapping scanning regions and improve the modeling efficiency of complex curved surfaces.

State Space and Action Design: State: The state includes a point cloud density distribution of a current scanning region (calculated via voxel grid statistics), a device attitude angle obtained by an inertial measurement unit (IMU) sensor embedded in the main unit, remaining battery power, and a type of external module (e.g., a structured-light module requiring close-range scanning). Action: An action includes outputting a scanning direction adjustment instruction (forward/backward, left/right, and pitch angle variations), controlling a scanning speed within a range of 0.1-1 m/s, and dynamically adjusting a laser emission frequency (automatically switching between high-frequency and low-frequency modes according to a distance). Reward Function: The reward function is defined with an effective point cloud growth rate per unit time as a core metric, where overlapping scanning regions are penalized (calculated based on a point cloud overlap rate), and dense sampling in high-curvature regions is rewarded.

Online Optimization Process: Initialization: After a scanning target is selected by a user, the main unit quickly captures an image of the target via the image acquisition module. The approximate shape of the object (e.g., a sphere, a box-shaped object, or a free-form surface) is identified using a You Only Look Once version 5 (YOLOv5) model, and a corresponding initial path template is loaded (e.g., a surrounding scanning pattern for the sphere and an orthogonal-face scanning pattern for the box-shaped object). Real-Time Planning: During scanning, a reinforcement learning agent updates a state once every 50 ms. Based on current point cloud data, uncovered regions are identified (void regions detected using an octree structure), and a next scanning pose suggestion is generated. The suggestion is presented to the user via the touch display screen to prompt adjustment of a handheld scanning angle (or, in future implementations, motor-assisted guidance may be provided). Experience Replay: After scanning is completed, path data from the current scan (state-action pairs) are stored in an experience pool. Offline training is periodically performed when the main unit is in a sleep state to gradually optimize scanning strategies for different object types.

In some embodiments, for dynamic scenarios (e.g., a slightly shaking to-be-measured object), a spatiotemporal joint registration model is proposed, in which timestamp information from lidar point clouds (temporally sparse), structured-light dense point clouds (temporally continuous), and image textures (high-frequency temporal sequences) is fused. Cross-modal spatiotemporal constraints are constructed through a Graph Optimization algorithm, thereby addressing the cumulative error problem encountered by conventional registration algorithms under dynamic conditions.

Construction of a spatiotemporal coordinate system includes assigning an independent timestamp synchronization module to each external module (based on a high-precision clock chip of the main unit), thereby ensuring that sampling data from the lidar (10 Hz), the structured-light module (30 Hz), and the image sensor (60 Hz) are associated with timestamps having nanosecond-level precision. A main unit-centered world coordinate system is established, and pose variations of the device during the scanning process are obtained through the IMU sensor, including a translation vector t and a rotation matrix R, thereby constructing a continuous-time pose trajectory T(t).

Dynamic Registration Process: Temporal Alignment: Data streams having different frequencies are subjected to interpolation and synchronization (e.g., lidar point clouds are interpolated to be aligned to a frame rate of the structured-light module), producing a unified dataset with uniform temporal intervals. Feature Association: In each frame of data, corner points (Harris3D features) in dense point clouds of structured light and SIFT features in images are extracted. Cross-modal feature matching pairs are established through a spatiotemporal consistency constraint (e.g., a pose change between adjacent frames≤5 mm). Graph Optimization Solution: A factor graph is constructed containing inter-module registration constraints and temporal pose constraints. Optimization variables are posing parameters of each frame and a global scale factor. An objective function minimizes reprojection errors of cross-modal features to output a globally consistent registration result.

In some embodiments, a scenario knowledge transfer model is constructed to learn general prior knowledge from historical user scanning data. When switching to a new scenario, optimal scanning parameters are rapidly adapted through transfer learning, thereby avoiding repeated debugging. A scenario classifier is embedded in the system to automatically identify a scanning environment (e.g., strong light/weak light, indoor/outdoor) and a target material (e.g., metal, plastic or ceramic), and to dynamically adjust operating parameters of the modules accordingly.

The corresponding input features include ambient light intensity (acquired by a light sensor of the main unit), target surface reflectivity (derived from grayscale value statistics of an image module), an external module configuration (e.g., whether a lidar module and a structured-light module are selected), and point cloud quality metrics from historical scans (e.g., noise density and void ratio). A lightweight convolutional neural network (CNN), such as MobileNetV3, is employed to classify scene images (environment overview images captured by a user), thereby outputting scene labels such as “industrial strong-light,” “cultural relics low-light” and “outdoor complex reflective” conditions.

Transfer Learning Process: Pre-training Phase: A large collection of scanning parameter configurations from public scenarios (e.g., NASA's space scanning parameters, automotive industry reflective surface parameters) is gathered. A general parameter optimization model is trained on a cloud server to extract a mapping relationship of “module gain-environmental noise-material reflectivity”. Local Transfer: When a new scenario (e.g., “ceramic cultural relics under low light”) is identified by the main unit, a subset of parameters related to “low-exposure image acquisition and structured light phase compensation” is transferred from the pre-trained model. Combined with a current hardware state of the device (e.g., a remaining battery level limiting a laser power), 5-10 key parameters (e.g., structured light projection brightness, laser emission pulse width) are fine-tuned using a Bayesian optimization algorithm.

During a first scan of a new scenario, a parameter adaptation time is shortened from a conventional 5-10 minutes to within 30 seconds, making it particularly suitable for emergency scanning (e.g., rescue digitization of cultural relics). Historical successful scanning parameters of a user are automatically incorporated into a local training set to form a dedicated scenario knowledge base, which becomes increasingly intelligent with use, thereby solving the problem of parameter rigidity of general-purpose devices in specific scenarios.

In some embodiments, for industrial quality inspection scenarios, a dedicated defect detection algorithm chain is designed: first, defect features in scanning data are enhanced via a GAN, followed by automated flaw recognition combined with weak supervision learning. The algorithm supports submillimeter-level localization of defects such as scratches and dents on a surface of a metal workpiece, and generates a three-dimensional quantitative report of the defects (depth, area and position coordinates).

Data Enhancement Module (GAN) includes a generator and a discriminator. Generator: Point cloud data containing defects is input, and an enhanced high-density point cloud (with defect edge details completed) is output. During training, standard defect data from industrial Computed Tomography (CT) scans is used as real samples, and resolution of defect features is improved through adversarial training. Discriminator: The discriminator distinguishes an enhanced point cloud from real CT data and assists the generator in optimization, ultimately improving edge accuracy of the enhanced defect point cloud to 0.1 mm.

The defect detection process includes reference modeling, difference calculation and intelligent classification. Reference Modeling: A standard workpiece without defects is scanned to generate a reference point cloud model. An alignment relationship between a measured workpiece and the reference point cloud model is established via an Iterative Closest Point (ICP) algorithm. Difference Calculation: A pointwise distance between a measured point cloud and the reference point cloud model is calculated to generate a distance heatmap. A threshold (e.g., 0.3 mm) is set to mark suspected defect regions. Intelligent Classification: Point cloud features (curvature change, normal vector anomaly) of the marked regions are classified using a Support Vector Machine (SVM), combined with a GAN-enhanced defect feature library. True defects (e.g., cracks) are distinguished from scanning noise, and a defect type (scratch/dent/protrusion) and a quantitative report are output.

In some embodiments, referring to FIGS. 1-5 and 7, an embodiment of the present disclosure provides an expandable handheld radar device includes a main unit 100. The main unit 100 includes a housing 110 and a first detection module 120 provided on the housing 110. The housing 110 is provided with an extension member 130 for connecting an external component 200.

With reference to the main unit 100, an XYZ coordinate system is established, where a Z-axis direction is parallel to a height direction of the main unit 100. Here, the Z-axis direction is defined as being parallel to a plumb line direction, specifically, a +Z-axis direction is defined as a direction opposite to the plumb line direction. An X-axis direction and a Y-axis direction are both orthogonal to the Z-axis direction, and may specifically be two orthogonal directions extending horizontally. Here, the X-axis direction is defined as being parallel to a length direction of the main unit 100, and the Y-axis direction is defined as being parallel to a width direction of the main unit 100. Additionally, the Y-axis direction is defined as a first direction, and the Z-axis direction is defined as a second direction.

The extension member 130 has a first wall 131 and a second wall 132 opposite to each other in the Y-axis direction (i.e., the first direction), and a third wall 133 intersecting the first wall 131 and the second wall 132. The first wall 131 and the second wall 132 are each provided with a groove 134 extending along the Z-axis direction (i.e., the second direction). Each groove 134 has two blocking side walls 134a and an opening 134b communicating with the third wall 133. The extension member 130 includes a slot 135. The slot 135 is provided on the first wall 131, the second wall 132 or a combination thereof. The third wall 133 is provided with a data interface 136. An engagement direction of the data interface 136 is parallel to the Z-axis direction.

The external component 200 includes a main body 210 and a locking member 220 movably mounted to the main body 210. The main body 210 includes two sliders 211 respectively cooperating with the two grooves 134. The locking member 220 is configured to move along the Y-axis direction. A side of the locking member 220 adjacent to the extension member 130 is provided with a first protrusion 221 cooperating with the slot 135. The main body 210 further includes a blocking wall portion 212 configured to shield the third wall 133 in the Z-axis direction.

The external component 200 and the extension member 130 can be engaged in the Z-axis direction through cooperation between the sliders 211 and the grooves 134. In an engaged state with the extension member 130, the external component 200 can be locked with the extension member 130 via the locking member 220 movably provided on the main body 210, specifically by inserting the first protrusion 221 into the slot 135, thereby restricting relative movement and separation of the external component 200 and the extension member 130 in the Z-axis direction. Restriction on two sides of each of the sliders 211 by the blocking side walls 134a can suppress shaking of the external component 200 in the X-axis direction in the engaged state, further ensuring connection stability between the external component 200 and the extension member 130. In the engaged state, the blocking wall portion 212 can shield the third wall 133, on which the data interface 136 is provided, in the Z-axis direction, thereby protecting the data interface 136. When the external component 200 is a functional extension member, a data connector may be provided on the blocking wall portion 212, such that the data connector and the data interface 136 can be synchronously mated during engagement between the external component 200 and the extension member 130 in the Z-axis direction.

The external component 200 includes a first accommodating region 230 penetrating the main body 210 in the Y-axis direction. The locking member 220 includes a rod body 222 provided in the first accommodating region 230. A middle portion of the rod body 222 is hinged to the main body 210, and is configured to rotate in a YZ plane. A first end of the rod body 222 is connected to the main body 210 via a biasing member 223 elastically deformable in the Y-axis direction. The first protrusion 221 is provided on a side of a second end of the rod body 222 adjacent to the extension member 130.

The rod body 222 may serve as a relatively simple implementation form of the locking member 220. The first end of the rod body 222, rotatably provided on the main body 210, can function as an operating end for manual unlocking, and the second end of the rod body 222 can function as a functional end for locking the external component 200 with the main unit 100. The biasing member 223 can retain the first protrusion 221 in the slot 135 by a force generated by its own elastic deformation, thereby maintaining the locked state between the external component 200 and the main unit 100. In this embodiment, a compression spring is used as the biasing member 223.

Considering product positioning, the first detection module 120 of the main unit 100 has relatively low requirements for detection accuracy. In the following embodiments, the first detection module 120 includes a first radar module 121 provided on a side of the housing 110 along a +Z-axis direction, and further includes two first optical lenses 122 provided on two sides of the housing 110 in the Y-axis direction. The two first optical lenses (122) may differ in functional configuration. For example, one of the two first optical lenses 122 may focus on capturing visual contours and texture information, while the other of the two first optical lenses 122 may focus on capturing environmental color information. Positions of the two first optical lenses 122 may be interchanged. The above is merely a configuration example of the first detection module 120. Based on different design schemes and positioning of the main unit 100, the first detection module 120 may have other configuration options.

A handle 400 is connected to the housing 110 on a side of the housing 110 along a −Z-axis direction for convenient gripping and operation by a user. A circuit system within the main unit 100 includes a main control module (not shown in the figures) electrically connected to the first detection module 120 and the data interface 136. Additionally, a battery (not shown in the figures) for supplying power to the circuit system is provided inside the main unit 100. The main control module and the battery may be of conventional configurations in the art and are not limited herein. The battery may be provided within the handle 400. The handle 400 is provided with a charging interface (not shown in the figures), such that the battery can be charged directly through the handle 400. Electrical connection between the main unit 100 and the handle 400 can be achieved via a power supply interface 140. A quick-release structure may also be introduced between the handle 400 and the main unit 100 to achieve a fixed connection, facilitating power continuation of the main unit 100 by replacing the handle 400 with another when the battery of one handle 400 is depleted. Furthermore, the expandable handheld radar device proposed herein may be used in the field of Simultaneous Localization and Mapping (SLAM).

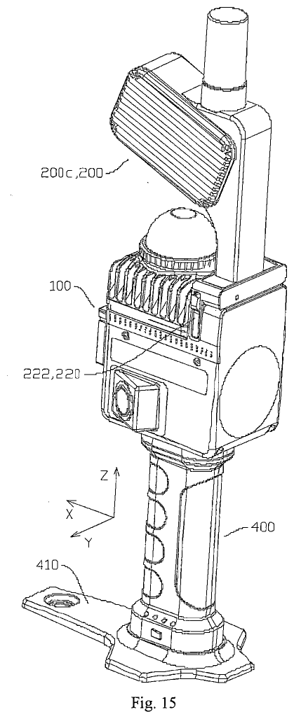

Referring to FIG. 15, in some embodiments, an end of the handle 400 may be connected to a base 410 to stably place the main unit 100, with the external component 200 connected thereto, on another object, or to further achieve a fixed connection with another object via the base 410.

### EXAMPLE 1

Referring to FIGS. 1-5, the handheld radar device proposed in this embodiment conforms to the foregoing general description in terms of both a basic structure and an engagement form with the external component 200. In this embodiment, a protective cover 200a is used as the external component 200. The extension member 130 is arranged based on a second protrusion 130a provided on a side of the housing 110 along a +X-axis direction. The first wall 131 and the second wall 132 are end walls of the second protrusion 130a in the Y-axis direction. The third wall 133 is an end wall of the second protrusion 130a in the Z-axis direction. Grooves 134 are located on sides of the first wall 131 and the second wall 132 adjacent to the housing 110. The extension member 130 further includes guide strips 137 formed on sides of the first wall 131 and the second wall 132 away from the housing 110. The slot 135 is recessedly provided on each of the guide strips 137. Blocking side walls 134a are each includes an end wall of the housing 110 in a +X-axis direction. The protective cover 200a further includes a guide groove 213 cooperating with the guide strips 137. The external component 200 is configured to shield the side of the second protrusion 130a along the +X-axis direction.

Providing the extension member 130 based on the second protrusion 130a protruding from the side of the housing 110 along the +X-axis direction allows the external component 200 connected thereto to be correspondingly located outside the main unit 100, thereby avoiding interference between the external component 200 and the main unit 100 during installation, and also helping to improve design freedom in terms of shape and size of the external component 200. Furthermore, in addition to cooperation between the sliders 211 and the grooves 134, the external component 200 and the extension member 130 can further cooperate via the guide strips 137 and the guide groove 213, further improving connection stability. Shielding the side of the second protrusion 130a along the +X-axis direction by the external component 200 can better protect the extension member 130 from damage caused by collision.

When the main unit 100 is used alone for surveying and mapping, the protective cover 200a does not need to be removed. Only when it is necessary to connect an external component 200 having a detection function for functional expansion does the protective cover 200a need to be removed first.

### EXAMPLE 2

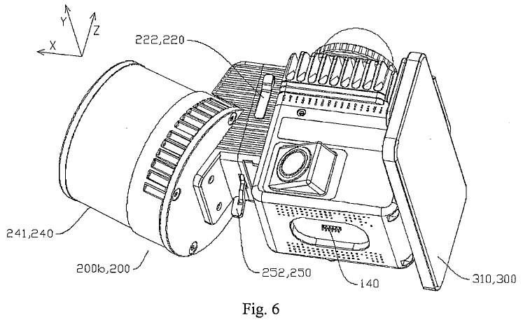

Referring to FIGS. 6-9, the handheld radar device proposed in this embodiment conforms to the foregoing general description in terms of both a basic structure and an engagement form with the external component 200. In this embodiment, a main extension component 200b having a second detection module 240 is used as the external component 200. The main extension component 200b includes a first data connector 214 matching the data interface 136. The main extension component 200b cooperates with the extension member 130, which is provided based on the second protrusion 130a in the Example 1, and a cooperation manner thereof is the same as that between the protective cover 200a and the second protrusion 130a. Related structural features adopt the same reference numerals as those in the Example 1.

On this basis, the main extension component 200b further includes an abutting member 250 movably provided on the main body 210. The abutting member 250 is configured to move in the X-axis direction, and to abut against a side of the second protrusion 130a along the +X-axis direction. A second accommodating region 260 is recessedly provided on a side of the main body 210 adjacent to the side of the second protrusion 130a along the +X-axis direction. A side of the second accommodating region 260 along a −X-axis direction is provided with a pivot shaft 261 and an arc-shaped inclined guide groove 262. The inclined guide groove 262 includes a flat bottom segment 262a and an inclined bottom segment 262b. The abutting member 250 is configured to rotate in a YZ plane. The abutting member 250 includes a pressing disc portion 251 and a lever portion 252. The pressing disc portion 251 includes a shaft groove 2511 cooperating with the pivot shaft 261 and a third protrusion 2512 cooperating with the inclined guide groove 262. The lever portion 252 is configured to extend through the second accommodating region 260 and a side of the main body 210 along the −Z-axis direction.

Introducing the abutting member 250 can further improve connection stability between the external component 200 and the main unit 100, preventing the main extension component 200b from shaking or swinging relative to the main unit 100 in the X-axis direction, thereby helping to ensure detection accuracy of the handheld radar device in a multi-measurement integration mode. By pivoting the lever portion 252, the pressing disc portion 251 can be rotated, whereby the third protrusion 2512 can slide along the flat bottom segment 262a of the inclined guide groove 262 to the inclined bottom segment 262b and finally move to abut against a side wall surface of the second accommodating region 260 along the −X-axis direction. Accordingly, the pressing disc portion 251 can move toward the second protrusion 130a in the X-axis direction and abut against the second protrusion 130a, thereby preventing the main extension component 200b from shaking or swinging relative to the main unit 100.

The main extension component 200b has a detection function and can be connected to a main control module of the main unit 100 via the first data connector 214, thereby achieving communication interaction with the main unit 100 and being powered by a battery of the main unit 100. Therefore, the main extension component 200b can serve as a supplement or enhancement to the surveying and mapping functions of the main unit 100, thereby enabling integration of multiple measurement functions.

The main extension component 200b, as an extension accessory that can be optionally purchased by a user at a later stage, does not significantly increase the overall volume or weight of the device after being mounted to the main unit. Compared with separately purchasing a main unit having equivalent surveying and mapping performance, the overall cost is reduced. Moreover, since the main extension component 200b shares the same movement trajectory as the main unit 100 after engagement, and is capable of real-time data synchronization, integration of multiple measurement functions is more readily achieved. In addition, considering that the main extension component 200b is connected to the main unit 100 via the extension member 130 with high connection stability, constraints on the weight and volume of the main extension component 200b are relatively small.

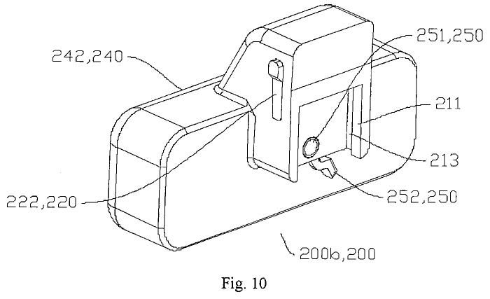

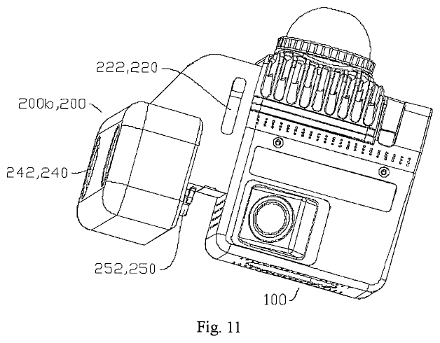

The configuration of the second detection module 240 is relatively diverse, and thus multiple implementation forms are provided in this embodiment. Referring to FIGS. 6-9, in this embodiment, a second radar module 241 is used as the second detection module 240 to enhance detection capabilities of the main unit 100. In some embodiments, a radar module with detection accuracy higher than that of a first radar module 121 is used as the second radar module 241. Referring to FIGS. 10 and 11, in an embodiment, an optical scanner 242 is used as the second detection module 240. The optical scanner 242 may be, for example, a grating scanner or a spot scanner. The optical scanner 242 is configured to enhance optical detection performance of the main unit 100, thereby facilitating modeling of small-sized objects. Grating scanners and spot scanners are not provided in existing handheld radar devices, and both fall within a category of three-dimensional scanning modules.

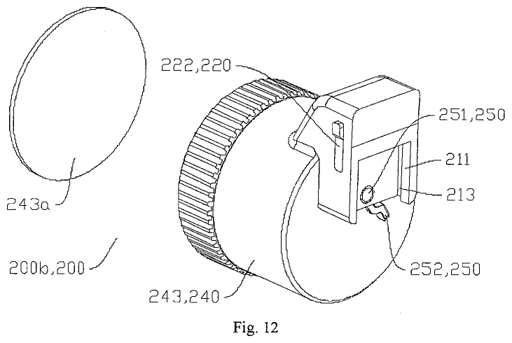

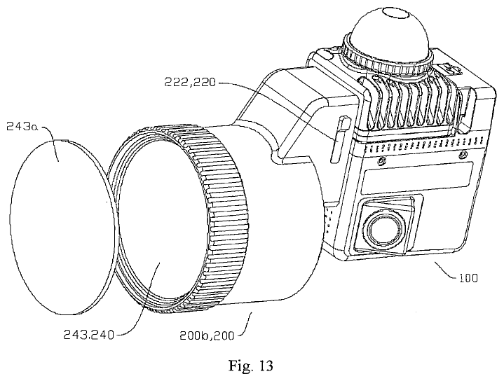

Referring to FIGS. 12 and 13, in an embodiment, a second optical lens 243 is used as the second detection module 240 to enhance optical detection capabilities of the main unit 100. In some embodiment, an optical lens with a resolution higher than that of a first optical lens 122 is used as the second optical lens 243. On this basis, a filter 243a may be mounted on the second optical lens 243 to improve performance thereof. The filter 243a may be regarded as an accessory of the second optical lens 243.

Accordingly, in this embodiment, the second detection module 240 may include a detection module of the same type as the first detection module 120, or a detection module of a different type from the first detection module 120. Both configurations are beneficial for improving overall detection efficiency and accuracy of the device. The above embodiments are merely exemplary configurations of the second detection module 240. In addition, both the first detection module 120 and the second detection module 240 may be selected from other types of detection modules with relatively mature technologies, such as a multispectral sensor module and an infrared imaging module.

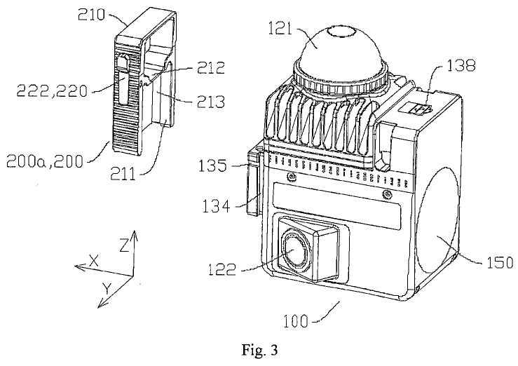

Referring to FIGS. 3 and 6, this embodiment further includes an external display component 300 communicatively connected to the main unit 100. The external display component 300 includes a display module 310. Both the main unit 100 and the external display component 300 are each provided with a wireless communication module (not shown in the figures). The external display component 300 is detachably mounted on the housing 110. In this embodiment, the external display component 300 is magnetically attached to the main unit 100. The main unit 100 is provided with a magnetic attachment module 150 on a side of the housing 110 along the −X-axis direction. In this embodiment, a smartphone having a wireless charging function is employed as the external display component 300. A magnetic attraction member (not shown in the figures) is provided within the smartphone, and is configured to function as a magnetic attachment module.

The external display component 300 can communicate with the main unit 100 and visually present surveying and mapping results in real time, enabling the user to perform detection and monitoring operations simultaneously, thereby helping to improve surveying and mapping efficiency. Existing smartphones typically include a display module 310 with relatively high definition and a wireless communication module, and can serve as the external display component 300 of the handheld radar device. After the user attaches their smartphone to the main unit 100 and completes the pairing process, the smartphone can function as the external display component 300, thereby eliminating the need to purchase a dedicated external display extension component, thereby saving hardware costs.

Considering that smartphones with wireless charging capabilities are built with a magnetic attraction member, providing a magnetic attachment module 150 inside the main unit 100 offers a relatively convenient connection solution between the main unit and the smartphone. A connection between the main unit 100 and the external display component 300 is not limited to magnetic attraction. In other embodiments, the housing 110 and the external display component 300 may be detachably connected by means such as snapping, fitting, or adhesive bonding.

In other embodiments, the external display component 300 may also be a dedicated accessory developed for the main unit 100. The external display component 300 may have a built-in power source, or may draw power from the main unit 100 via a related physical interface. The external display component 300 and the main unit 100 may adopt a wireless communication mode or may achieve communication interaction via a physical data interface. Such a customized solution of the external display component 300 can ensure a high degree of adaptability with the main unit 100.

### EXAMPLE 3

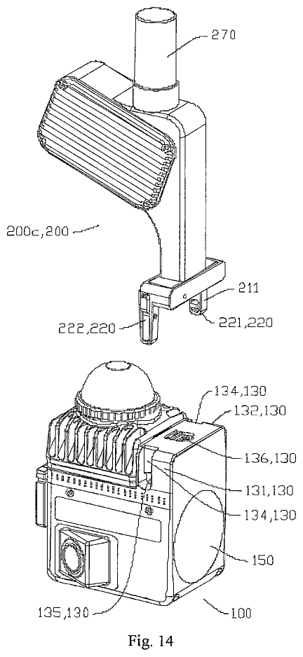

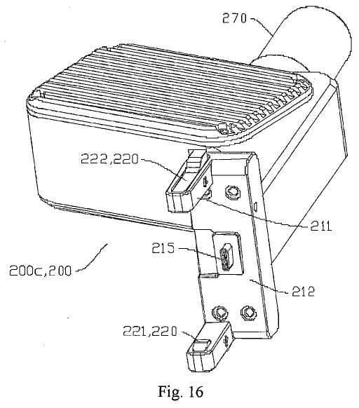

Referring to FIGS. 14-16, the handheld radar device provided in this embodiment conforms to the foregoing general description in terms of both a basic structure and an engagement form with the external component 200. In this embodiment, an auxiliary extension component 200c having a third detection module 270 is used as the external component 200. The auxiliary extension component 200c includes a second data connector 215. The third detection module 270 mounted on the auxiliary extension component 200c is provided with a Real-Time Kinematic (RTK) high-precision positioning module, which can provide real-time position information to the main unit 100. The RTK high-precision positioning module is compact, and has no special requirements regarding an installation position on the radar device, making it suitable for use as the third detection module 270.

In this embodiment, the extension member 130 is provided based on the housing 110. The first wall 131 and the second wall 132 are two side walls of the housing 110 opposite to each other in the Y-axis direction. The first wall 131 and the second wall 132 are each provided with the slot 135. The third wall 133 corresponds to an end wall of the housing 100 along the −Z-axis direction.

Introducing the auxiliary extension component 200c can also cooperate with the first detection module 120 to enhance performance of the main unit 100. The extension member 130 provided based on the housing 110 can utilize an arrangement space on a side of the housing 100 along the −Z-axis direction for functional extension. The auxiliary extension component 200c is secured to the main unit 100 via two locking members 220 engaging with the corresponding slots 135, ensuring stable connection between the auxiliary extension component 200c and the main unit 100.

To protect the data interface 136 when the auxiliary extension component 200c is not connected, a soft-rubber cover 138 is provided on the housing 110 in this embodiment to cover the data interface 136. An end of the soft-rubber cover 138 is fixedly connected to the housing 110, preventing loss.

In some embodiments, the handheld radar device based on a “primary positioning main unit and high-precision extension plug-in” is proposed, allowing flexible switching between different accuracies and functionalities through a modular design. The main unit integrates a low-cost, low-power primary detection module to achieve centimeter-level preliminary positioning. External components can be replaced with functional plug-ins such as a high-precision 3D radar, a grating scanner or an infrared sensor, which can be quickly connected to the main unit via a standardized extension interface to meet diverse requirements such as large-scene modeling, precision measurement and multispectral detection.

Main unit Part: The centimeter-level preliminary positioning module (main unit) includes: a first detection module, which includes a low-cost 2D radar module (e.g., a single-line or low-line-count mechanical rotating radar with an accuracy of ±5 cm) and dual optical lenses (a left lens as a grayscale camera for capturing contour and texture information, and a right lens as a color camera for capturing environmental color information), all arranged on a side (top) of the housing along the +Z-axis direction. Together with the main control module, the first detection module enables preliminary positioning by fusing visual and radar data (SLAM algorithm). Extension member: The extension member is located on a side of the housing (on two sides of the housing in the Y-axis direction), and includes grooves extending along the Z-axis direction (with blocking side walls to limit X-axis shaking), slots (on the first and second walls opposite to each another in the Y-axis direction), and a data interface (e.g., a Type-C or customized high-speed interface with an engagement direction parallel to the Z-axis direction) on a third wall. Handle: A side (bottom) of the housing along the −Z-axis direction is connected to a quick-release handle. The quick-release handle has a built-in battery and a charging interface. The handle is electrically connected to the main unit via a power supply interface, supporting hot-swappable battery replacement. A base may be installed at an end of the handle for placing the device flat or securing the device. The main unit scans the environment contours using the 2D radar, combined with dual-lens visual data. The main control module calculates centimeter-level positioning coordinates and a preliminary environmental map in real time, providing a basic positioning framework for external high-precision plug-ins and reducing computational load for subsequent fine modeling.

High-precision extension plug-in (external component) includes the following components: High-precision 3D modeling plug-in (e.g., Hesai XT32 MAX Radar Plug-in): A main body: sliders on two sides that are embedded in the grooves of the main unit and slidably engaged along the Z-axis direction. A blocking wall portion covers the third wall, and a high-speed data connector (e.g., an Ethernet interface) matching the data interface is built therein, which automatically connects to a main control module of the main unit upon engagement. Locking member: A middle portion of a rod body is hinged to the main body, with a first end as a manual release handle (exposed in Y-axis direction) and a second end having a protrusion that snaps into the slot of the main unit. A compression spring maintains a locked state, preventing separation in the Z-axis direction. The plug-in is equipped with a high-precision solid-state lidar, which quickly aligns with the main unit using preliminary positioning data provided thereby, generating a 3D point cloud map with millimeter-level accuracy, suitable for large-scene digitization requirements such as architectural scanning and industrial modeling. Precision measurement plug-in (e.g., grating/spot scanner): A main body integrates a line laser emitter and a high-resolution camera to form a triangulation measurement structure. Sliders and a locking member are designed in accordance with the main unit's standard specifications, ensuring synchronous connection of data interfaces upon Z-axis engagement. By projecting grating fringes or laser spots onto a surface of a measured object, combined with deformed images captured by the camera, three-dimensional topography with submillimeter-level accuracy is calculated, suitable for small-object modeling such as precision part inspection and cultural relic digitization. Functional detection plug-in (e.g., infrared scanner): A main body has a built-in infrared thermal imaging sensor and a multispectral filter, and a data connector on a blocking wall portion supports high-speed image transmission. No additional power supply is required (power is uniformly supplied by a main unit battery or a handle battery). Environmental thermal radiation data and visible light images are synchronously collected to generate a temperature-vision fusion map, used for scenarios such as industrial equipment fault detection and security monitoring.

Modular switching process includes the following steps: Installing a plug-in: The plug-in is inserted along the Z-axis direction of the extension member of the main unit, with sliders sliding along the grooves to a bottom. The locking member is manually pressed to snap the protrusion into the slot, completing mechanical locking and data interface connection. Function activation: The main control module of the main unit identifies a type of the plug-in (via a handshake protocol through the data interface) and automatically switches to a corresponding algorithm (e.g., a high-precision modeling algorithm or a spectral analysis algorithm), fusing preliminary positioning data of the main unit with high-precision data of the plug-in. Removing the plug-in: The first end of the locking member is pulled to unlock, a biasing member elastically returns to disengage the protrusion from the slot, and the plug-in is pulled out along the Z-axis direction, allowing switching without requiring tools.

Technical advantages corresponding to this embodiment include the following aspects: Hierarchical positioning architecture: Low-cost preliminary positioning of the main unit reduces system power consumption and computational load, while external plug-ins enhance precision or expand functions as needed, balancing performance and cost. Standardized interface design: Through mechanical guiding of grooves and sliders, locking of slots and locking members, and automatic docking of Z-axis data interfaces, “plug-and-play” functionality for plug-ins is achieved, compatible with sensors from multiple manufacturers (subject to data protocol adaptation). Battery life and portability: The quick-release handle supports hot-swappable battery replacement, and the base adapts to various installation scenarios, accommodating both handheld mobile operation and fixed platform deployment.

Corresponding application scenarios Construction engineering include the following aspects: The main unit performs preliminary positioning to construct a site contour, and an external high-precision radar generates a Building Information Modeling (BIM) model. Industrial quality inspection: A grating scanner is installed to inspect surface defects of parts (with submillimeter-level accuracy). Security patrol: An infrared plug-in is switched to enable nighttime thermal imaging monitoring while simultaneously recording positioning coordinates. Thus, the handheld radar device achieves modular upgrades from “basic positioning” to “fine operations”, meeting differentiated requirements for precision and functionality across different industries.

Described above are merely illustrative, and are not intended to limit the scope of the present disclosure. It should be understood that various modifications, changes and replacements made by those skilled in the art without departing from the spirit of the disclosure shall fall within the scope of the present disclosure defined by the appended claims.

What is claimed is:

1. A detachable handheld laser scanner system supporting multiple plug-in combinations, comprising:
a main unit;
an extension member; and
a plurality of external components;
wherein a housing of the main unit is provided with the extension member;
the extension member comprises an engagement cavity, a data interface and a clamping part; the engagement cavity is recessed on a side of the housing along a first direction; the data interface is provided on an inner wall of the engagement cavity; and the clamping part is movably provided in the housing;
the engagement cavity has a first side wall and a second side wall opposite to each other in a second direction, wherein the second direction intersects the first direction;
the clamping part is provided with a limiting portion configured to act on the plurality of external components;
the plurality of external components comprise a lidar module, a structured-light scanning module, an image acquisition module or a combination thereof;
each of the plurality of external components is provided with an engagement portion configured to engage with the engagement cavity;
a surface of the engagement portion is provided with a data connector configured to mate with the data interface;
in response to a case that each of the plurality of external components is inserted into the engagement cavity along the first direction, the engagement portion is engaged with the engagement cavity in the first direction, the clamping part is configured to be operated to cause the limiting portion to abut against the engagement portion together with the first side wall in the second direction to achieve a locked state between the main unit and the plurality of external components, and the data connector is configured to mate with the data interface to establish data communication;
in response to a case that the clamping part is operated to allow a distance between the limiting portion and the first side wall in the second direction to be not smaller than a distance between the first side wall and the second side wall, each of the plurality of external components is configured to disengage from the engagement cavity along the first direction to achieve an unlocked state;
the main unit is configured to be selectively connected to corresponding one or more of the plurality of external components according to different application scenarios through a detachable connection between the extension member and the corresponding one or more of the plurality of external components, so as to realize a point-cloud accuracy enhancement function, a micro-target modeling function, an image-texture fusion function or a combination thereof;
an outer contour of the engagement portion is configured to match a contour of the inner wall of the engagement cavity;
at least two side walls of the engagement portion are each provided with a guide rib extending along the first direction; and the inner wall of the engagement cavity is provided with a guide groove configured to slidably receive the guide rib;
the data connector is configured as a contact-type connector;
the data interface is configured as an elastic contact piece set adapted to the contact-type connector;
the elastic contact piece set is electrically connected to a main control chip of the main unit through a flexible printed circuit board;
the clamping part comprises a push rod slidably provided in the housing;
a first end of the push rod is configured to extend outside the housing to form an operating portion, and a second end of the push rod is oriented toward the engagement cavity and is provided with the limiting portion;
the limiting portion is configured as a wedge-shaped protrusion inclined toward the first side wall;
the engagement portion is provided with a limiting slot at a position corresponding to the wedge-shaped protrusion, and the limiting slot is configured to engage with the wedge-shaped protrusion; and
in response to a case that the operating portion is pushed along the second direction, the wedge-shaped protrusion is configured to be inserted into the limiting slot and to abut against the first side wall to achieve the locked state.

2. The detachable handheld laser scanner system of claim 1, wherein a return spring is provided between the push rod and the housing;
a first end of the return spring is connected to the push rod, and a second end of the return spring is connected to an inner wall of the housing;
in response to a case that no external force is applied to the operating portion, the return spring is in a naturally-extended state, and a distance between the wedge-shaped protrusion and the first side wall is greater than a width of the limiting slot; and
in response to a case that an external force is applied to pull the operating portion in a direction away from the first side wall, the distance between the wedge-shaped protrusion and the first side wall increases to be not less than the distance between the first side wall and the second side wall, thereby achieving the unlocked state.

3. The detachable handheld laser scanner system of claim 1, wherein a sealing ring is provided at an opening edge of the engagement cavity;
the sealing ring is configured to extend along the first direction and abut against a front-end surface of the engagement portion to enable the detachable connection between the extension member and the corresponding one or more of the plurality of external components;
a bottom of the engagement cavity is provided with a pressure sensor; and
the pressure sensor is electrically connected to the main control chip of the main unit, and is configured to detect whether the corresponding one or more of the plurality of external components is fully inserted into the engagement cavity.

4. The detachable handheld laser scanner system of claim 1, wherein in response to a case that a selected one of the plurality of external components is the lidar module, the main control chip of the main unit is configured to invoke a point-cloud denoising algorithm to perform outlier filtering and density equalization on point cloud data acquired by the lidar module, thereby realizing the point-cloud accuracy enhancement function; and
in response to a case that a selected one of the plurality of external components is the structured-light scanning module, the main control chip of the main unit is configured to parse fringe images projected by the structured-light scanning module based on a Gray code decoding algorithm to generate three-dimensional point cloud data of a micro target, thereby realizing the micro-target modeling function.

5. The detachable handheld laser scanner system of claim 4, wherein in response to a case that among the plurality of external components, the image acquisition module and the lidar module are simultaneously selected, the main control chip of the main unit is configured to execute a multimodal data registration algorithm through steps of:
acquiring a surface texture image of a target through the image acquisition module, and acquiring point cloud data of the target through the lidar module;
performing feature matching based on feature points in the texture image and three-dimensional coordinates in the point cloud data to generate a texture-point cloud mapping table; and
fusing the texture image into the point cloud data according to the texture-point cloud mapping table to realize the image-texture fusion function.

6. The detachable handheld laser scanner system of claim 1, wherein a surface of the housing of the main unit is provided with a status indicator light and a touch display screen;
the status indicator light is electrically connected to the main control chip, and is configured to indicate connection states of the plurality of external components;
the touch display screen is configured to receive a scenario selection instruction input by a user; and
the main control chip is configured to retrieve, in response to the scenario selection instruction, a scanning parameter configuration file corresponding to selected one or more of the plurality of external components;
wherein the scanning parameter configuration file comprises a laser emission frequency, a structured-light projection period and an image acquisition frame rate.

7. The detachable handheld laser scanner system of claim 1, wherein the main control chip of the main unit comprises an identification module; and
the identification module is configured to:
send, through the data interface, an identity query instruction to the corresponding one or more of the plurality of external components in response to a case that the corresponding one or more of the plurality of external components is inserted into the engagement cavity and the data connector is mated with the data interface;
receive identification information returned from the corresponding one or more of the plurality of external components; and
retrieve a corresponding driver program from a preset component driver library based on the identification information to control operation of corresponding hardware and perform data format conversion.

8. The detachable handheld laser scanner system of claim 1, wherein a rear end of the engagement portion of each of the plurality of external components is provided with an electromagnetic adsorption layer;
a bottom of the engagement cavity is provided with a magnetic base corresponding to the electromagnetic adsorption layer, and the magnetic base is configured to cooperate with the electromagnetic adsorption layer;
the magnetic base is electrically connected to a power supply module of the main unit;
in response to a case that the corresponding one or more of the plurality of external components is inserted into the engagement cavity and in the locked state, the power supply module of the main unit is configured to supply power to the magnetic base, such that an electromagnetic attraction force is generated between the electromagnetic adsorption layer and the magnetic base; and
in response to a case that the corresponding one or more of the plurality of external components are in the unlocked state, the power supply module of the main unit is configured to cut off power supply to the magnetic base, such that the electromagnetic attraction force disappears.
